(19) United States
(12) Patent Application Publication
(10) Pub. No.: US 2024/0006855 A1
(43) Pub. Date: Jan. 4, 2024

(54) METHODS AND SYSTEMS FOR SELF-ALIGNED VERTICAL CAVITY SURFACE EMITTING LASER (VCSEL)-ARRAY BEAM SHAPING

(71) Applicant: Sense Photonics, Inc., Durham, NC (US)

(72) Inventors: Hod Finkelstein, Berkeley, CA (US); James CARTER, Chapel Hill, NC (US); Scott BURROUGHS, Raleigh, NC (US)

(21) Appl. No.: 18/249,576

(22) PCT Filed: Oct. 22, 2021
(86) PCT No.: PCT/US2021/056217

§ 371 Date: Apr. 19, 2023

Related U.S. Application Data
(60) Provisional application No. 63/104,731, filed on Oct. 23, 2020.

(51) Int. Cl. H01S 5/183; G01S 7/481; G01S 7/497; G01S 17/894

(52) U.S. Cl. CPC H01S 5/18388; G01S 7/4815; G01S 7/4972; G01S 17/894

(57) ABSTRACT

An optical emitter device includes a plurality of emitters on a first substrate, and one or more alignment patterns on the first substrate and positioned relative to the plurality of emitters. At least one optical element is arranged to receive respective light emissions from the plurality of emitters, and is oriented based on the one or more alignment patterns, such that the at least one optical element and the plurality of emitters are self-aligned. Related devices and fabrication methods are also discussed.

### CLAIM OF PRIORITY

This application claims priority from U.S. Provisional Patent Application Ser. No. 63/104,731, filed Oct. 23, 2020, the disclosure of which is incorporated by reference herein in its entirety.

### FIELD

The present disclosure relates to semiconductor-based light emitting devices and related devices and methods of operation.

### BACKGROUND

Many emerging technologies, such as Internet-of-Things (IoT) and autonomous navigation, may involve detection and measurement of distance to objects in three-dimensional (3D) space. For example, automobiles that are capable of autonomous driving may require 3D detection and recognition for basic operation, as well as to meet safety requirements. 3D detection and recognition may also be needed for indoor navigation, for example, by industrial or household robots or toys.

Light based 3D measurements may be superior to radar (low angular accuracy, bulky) or ultra-sound (very low accuracy) in some instances. For example, a light-based 3D sensor system may include a detector (such as a photodiode or camera) and a light emitting device (such as a light emitting diode (LED) or laser diode) as light source, which typically emits light outside of the visible wavelength range. A vertical cavity surface emitting laser (VCSEL) is one type of light emitting device that may be used in light-based sensors for measurement of distance and velocity in 3D space. Arrays of VCSELs may allow for power scaling and can provide very short pulses at higher power density.

### SUMMARY

Some embodiments described herein provide methods, systems, and devices including electronic circuits that provide an optical emitter having one or more light emitter elements (including one or more semiconductor lasers, such as surface- or edge-emitting laser diodes, including vertical cavity surface emitting lasers (VCSELs); generally referred to herein as emitters).

According to some embodiments, an optical emitter device includes a plurality of emitters on a first substrate; one or more alignment patterns on the first substrate, where the one or more alignment patterns are positioned relative to the plurality of emitters; and at least one optical element arranged to receive respective light emissions from the plurality of emitters, where the at least one optical element is oriented based on the one or more alignment patterns.

In some embodiments, the emitters are arranged in an array, and the one or more alignment patterns are positioned adjacent a periphery of the array.

In some embodiments, the one or more alignment patterns comprise fiducial structures that extend along the periphery of the array.

In some embodiments, the plurality of emitters are provided on an intermediate substrate, the intermediate substrate is on a surface of the first substrate, and the fiducial structures extend along edges of the intermediate substrate.

In some embodiments, the fiducial structures protrude from a surface of the first substrate.

In some embodiments, the at least one optical element comprises a second substrate having edges and/or corners that are aligned based on the one or more alignment patterns.

In some embodiments, the second substrate comprises a first surface facing the plurality of emitters and a second surface opposite the first surface, where the second surface comprises a structured optical surface.

In some embodiments, the first surface of the second substrate directly contacts one or more of the emitters.

In some embodiments, the first surface of the second substrate is separated from the emitters by a gap therebetween.

In some embodiments, one or more pedestal structures attach the second substrate to the first substrate, where a height of the one or more pedestal structures is configured to provide a portion of a spacing between the emitters and the second surface of the second substrate.

In some embodiments, an adhesive pattern is between the one or more pedestal structures and the first substrate, where a thickness of the adhesive pattern is configured to provide a portion of the spacing.

In some embodiments, one or more spacer structures are between the first substrate and the first surface of the second substrate, where a height of the one or more spacer structures is configured to provide a portion of the spacing.

In some embodiments, the one or more spacer structures is integral to the second substrate or the intermediate substrate.

In some embodiments, the one or more pedestal structures extend onto the intermediate substrate to provide a portion of the spacing.

In some embodiments, the one or more alignment patterns comprise a corner of a frame structure that is positioned adjacent the periphery of the array.

In some embodiments, a coefficient of thermal expansion (CTE) of the second substrate is greater than that of the first substrate and/or the intermediate substrate.

In some embodiments, respective local optical axes of the structured optical surface are oriented independent of respective optical axes of the plurality of emitters.

In some embodiments, the structured optical surface comprises a diffractive optical element.

In some embodiments, the first substrate and/or the intermediate substrate having the emitters thereon is a non-native substrate.

According to some embodiments, a method of fabricating an optical emitter device includes providing a plurality of emitters on a first substrate; providing one or more alignment patterns on the first substrate, where the one or more alignment patterns are positioned relative to the plurality of emitters; and arranging at least one optical element to receive respective light emissions from the plurality of emitters, where the at least one optical element is oriented based on the one or more alignment patterns.

In some embodiments, providing the emitters and providing the one or more alignment patterns comprises providing the emitters in an array on the first substrate; and providing the one or more alignment patterns adjacent a periphery of the array.

In some embodiments, providing the one or more alignment patterns comprises providing fiducial structures on the first substrate that extend along the periphery of the array.

In some embodiments, providing the emitters on the first substrate comprises providing the emitters on an intermediate substrate; and providing the intermediate substrate on a surface of the first substrate, where the fiducial structures extend along edges of the intermediate substrate.

In some embodiments, the fiducial structures protrude from a surface of the first substrate. Providing the fiducial structures may include transfer-printing the fiducial structures on the first substrate.

In some embodiments, the at least one optical element comprises a second substrate, and arranging the at least one optical element comprises aligning edges and/or corners of the second substrate based on the one or more alignment patterns.

In some embodiments, the second substrate comprises a first surface facing the plurality of emitters and a second surface opposite the first surface, where the second surface comprises a structured optical surface.

In some embodiments, the second substrate is attached to the first substrate by one or more pedestal structures, where a height of the one or more pedestal structures is configured to provide a portion of a spacing between the emitters and the second surface of the second substrate.

In some embodiments, an adhesive pattern is provided on the one or more pedestal structures and/or on the first substrate, where a thickness of the adhesive pattern is configured to provide a portion of the spacing.

In some embodiments, one or more spacer structures are provided on the first substrate, where a height of the one or more spacer structures is configured to provide a portion of the spacing. Providing the one or more spacer structures may be performed using a transfer-printing process.

In some embodiments, providing the one or more alignment patterns comprises providing a frame structure on the first substrate adjacent the periphery of the array, where the one or more alignment patterns comprise a corner of the frame structure.

In some embodiments, providing the emitters comprises transferring the emitters from a native source substrate to the first substrate or to the intermediate substrate using a transfer-printing process.

In some embodiments, the optical emitter device is configured to be coupled to a vehicle and oriented relative to an intended direction of travel of the vehicle.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic block diagram illustrating an emitter array and other components of a ToF measurement system or circuit in a lidar application according to some embodiments of the present disclosure.

FIGS. 2A, 3A, 4A, 5A, 6A, 7A, and 8A are plan views of emitter arrays including substrates configured for self-aligned optical element(s) according to some embodiments of the present disclosure.

FIGS. 2B, 3B, 4B, 5B, 6B, 7B, and 8A are cross-sectionals view taken along line B-B′ of FIGS. 2A, 3A, 4A, 5A, 6A, 7A, and 8A respectively, illustrating the self-aligned optical element(s) mounted on the emitter arrays according to some embodiments of the present disclosure.

FIG. 9 is an enlarged cross-sectional view illustrating local optical axes of the optical element relative to respective optical axes of the emitters according to some embodiments of the present disclosure.

### DETAILED DESCRIPTION OF EMBODIMENTS

In the following detailed description, numerous specific details are set forth to provide a thorough understanding of embodiments of the present disclosure. However, it will be understood by those skilled in the art that the present disclosure may be practiced without these specific details. In some instances, well-known methods, procedures, components and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

Embodiments of the present disclosure describe methods for assembling optical elements and aligning optical beams generated by emitter arrays, such as VCSEL arrays, or other arrays of emitters formed or placed on a common substrate. Embodiments of the present disclosure can be applied in lidar systems, illumination systems (such as vehicle headlights) and/or other illumination imagers that may use arrays of discrete emitters, such as LEDs or VCSELs.

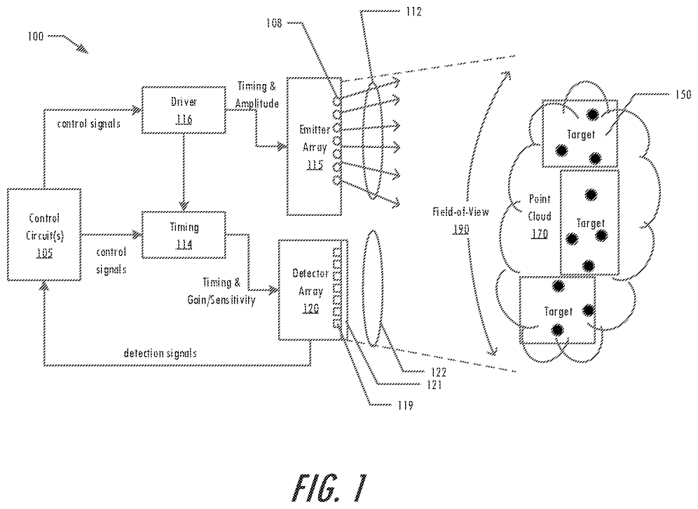

An example application of embodiments of the present disclosure in a lidar system or circuit 100 is shown in FIG. 1. The lidar system 100 includes a control circuit 105, a timing circuit 114, lidar emitter implemented as an emitter array 115 including a plurality of emitters 108, and a lidar detector implemented as a detector array 120 including a plurality of detectors 119. The detectors 119 include time-of-flight sensors (for example, an array of single-photon detectors, such as SPADs). One or more of the emitter elements 108 of the emitter array 115 may define emitter units that respectively emit a radiation pulse or continuous wave signal at a time and frequency controlled by a timing generator or driver circuit 116. In particular embodiments, the emitters 108 may be pulsed light sources, such as LEDs or lasers (such as vertical cavity surface emitting lasers (VCSELs)), that are configured to emit light with the operational wavelength range of the lidar system 100. Radiation is reflected back from a target 150, and is sensed by detector pixels defined by one or more detector elements 119 of the detector array 120. The control circuit 105 implements a pixel processor that measures and/or calculates the time of flight of the illumination pulse over the journey from emitter array 115 to target 150 and back to the detectors 119 of the detector array 120, using direct or indirect ToF measurement techniques.

The emitter module or circuit 115 may include an array of emitter elements 108 (e.g., VCSELs), a corresponding array of optical elements 112 coupled to one or more of the emitter elements (e.g., lens(es) 112, such as microlenses), and/or driver electronics 116. The optical elements 112 may be configured to provide a sufficiently low beam divergence of the light output from the emitter elements 108 so as to ensure that respective fields of illumination of either individual or groups of emitter elements 108 do not significantly overlap, and yet provide a beam divergence of the light output from the emitter elements 108 to provide eye safety to observers. In some embodiments, the emitters 108 may be provided on a non-planar (e.g., curved) or flexible substrate so as to contribute to the desired illumination pattern.

The driver electronics 116 may each correspond to one or more emitter elements, and may each be operated responsive to timing control signals with reference to a master clock and/or power control signals that control the peak power of the light output by the emitter elements 108. In some embodiments, each of the emitter elements 108 in the emitter array 115 is connected to and controlled by a respective driver circuit 116. In other embodiments, respective groups of emitter elements 108 in the emitter array 115 (e.g., emitter elements 108 in spatial proximity to each other), may be connected to a same driver circuit 116. The driver circuit or circuitry 116 may include one or more driver transistors configured to control the modulation frequency, timing and amplitude of the optical signal emission that is output from the emitters 108. The maximum optical power output of the emitters 108 may be selected to generate a signal-to-noise ratio of the echo signal from the farthest, least reflective target at the brightest background illumination conditions that can be detected in accordance with embodiments described herein.

Light emission output from one or more of the emitters 108 impinges on and is reflected by one or more targets 150, and the reflected light is detected as an optical signal (also referred to herein as a return signal, echo signal, or echo) by one or more of the detectors 119 (e.g., via receiver optics 122 and/or wavelength-selective filter(s) 121), converted into an electrical signal representation (referred to herein as a detection signal), and processed (e.g., based on time of flight) to define a 3-D point cloud representation 170 of a field of view 190.

Operations of lidar systems in accordance with embodiments of the present disclosure as described herein may be performed by one or more processors or controllers, such as the control circuit 105 of FIG. 1. For example, the control circuit 105 may implement a pixel processor that measures the ToF of the laser pulse and its reflected signal over the journey from emitter array 115 to object 150 and back to the detector array 110. The processor circuit 105′ may also include a sequencer circuit that is configured to coordinate operation of the emitters 108 and detectors 119.

Emitter arrays in accordance with embodiments of the present disclosure may be used in both electrically-scanning (which generate image frames by raster scanning; also referred to herein as e-scanning) and flash or staring lidar systems (where the pulsed light emitting device array 115 emits light for short durations over a relatively large area to acquire images). The description above is primarily with reference to direct ToF (dToF) lidar systems, but it will be understood that embodiments described herein can be applied to indirect ToF (iToF) lidar systems as well.

Still referring to FIG. 1, the emitters 108 may be electrically connected surface-emitting laser diodes, such as VCSELs, and may be operated with strong single pulses at low duty cycle or with pulse trains, typically at wavelengths outside of the visible spectrum (e.g., greater than about 900 nanometers (nm), for example, about 905 nm for GaAs VCSELs or about 1500 nm for InP VCSELs). The distribution or population density of the emitters 108 in the emitter array 115 can be selected to define a sparse array (e.g., with a large or varying pitch between adjacent emitters in plan view, in some embodiments relative to the size of the emitter aperture). The operation of the emitters 108 can be dynamically adjusted or otherwise controlled to reduce optical power density, providing both long range and eye safety at a desired wavelength of operation. Because of sensitivity to background light and the decrease of the signal with distance, several watts of laser power may be used to detect a target 150 at a distance d of up to about 100 meters or more.

Often the raw combined output of the emitters 108 (in lidar and/or other applications) may not be sufficiently uniform in intensity. For example, it may be desirable to homogenize and/or to shape the respective light emissions from the emitters 108 and output a single light beam or light pattern with a specific shape, such as a top hat (i.e., a near uniform intensity distribution within a given area) or other predefined spatial distribution.

Some embodiments described herein provide light emitting devices, such as surface-emitting laser diodes (e.g., VCSELs), configured as emitter arrays that include beam shaping structures that can be self-aligned with the light emitting devices to output arbitrary or desired distributions of light intensity as a function of field of view angle, using light that originates from multiple discrete light emitting devices of the array. In some embodiments, the light beam output from the beam shaping structures may define a substantially uniform intensity distribution over a field of view of the laser array. For example, the field of view angle may be about 80 degrees to about 180 degrees in some embodiments, or greater than about 150 degrees in some embodiments.

Beam shaping may be achieved using discrete optical components, such as an array of macro lenses. However, such configurations are typically large, expensive, and can require careful co-alignment of many lenses. Diffusers may also be used to shape the beam. Some diffusers may only be able to shape the beam on a single axis, e.g., the Y axis. Some diffusers may not be able to achieve a desired beam shape, e.g., top hat. Some diffusers are designed for operation with collimated beams, which may be incompatible with emitter arrays that do not emit collimated light. Integrated optical elements, such as microlenses, may also be fabricated monolithically on the emitter array. Such optical elements may have limited performance such as a limited f-number and/or a limited focal length, which may limit ability to shape the beam, e.g., to collimate the beam. Also, integrating such optical elements monolithically on the array may require technologies which may not be readily available and/or may add cost.

Structured optical surfaces (also referred to herein as patterned or structured surfaces) can be applied to control light from emitter arrays and to distribute it in a highly efficient manner. Structured surfaces as described herein may include, but are not limited to, diffractive optical elements (DOEs; such as subwavelength structured surfaces (SWS)), diffusers, microlens arrays that are formed separately from the emitter array, and polarization filters and vortex plates. These surfaces may require alignment with respect to the emitter array in order to perform as designed. Such alignment may sometimes be implemented using active alignment techniques, which may be time consuming and expensive.

Some embodiments of the present disclosure provide methods and systems for aligning optical elements (e.g., including structured surfaces) with a distributed array of emitters on a substrate in one or more dimensions, for example, along angular dimensions (e.g., Theta (θ), Phi (φ)), and linear dimensions (e.g., along X-, Y-, and/or Z-axes). In some embodiments, the emitter array can be formed or placed on multiple co-planar or co-aligned surfaces.

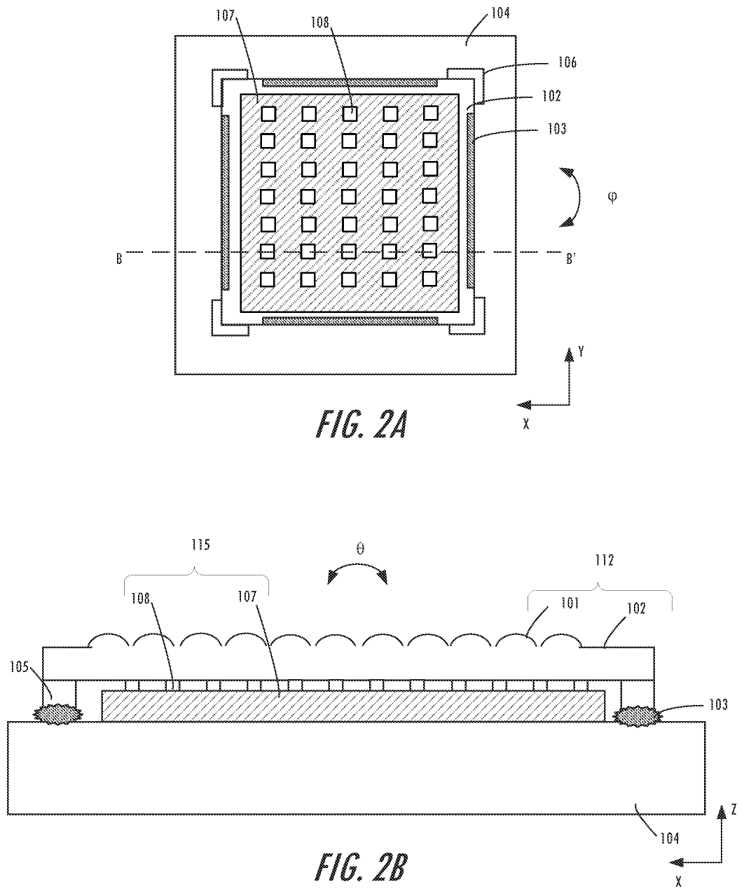

Devices and fabrication methods in accordance with embodiments of the present disclosure are describe below with reference to the examples of FIGS. 2A-2B to 8A-8B. It will be understood that elements of such devices and methods may be implemented as shown or in various combinations with one another.

FIG. 2A is a plan view of an emitter array on a substrate that is configured for implementing self-aligned optical element(s) in accordance with some embodiments of the present disclosure. FIG. 2B is a cross-sectional view taken along line B-B′ of FIG. 2A, with the self-aligned optical element(s) mounted on the emitter array.

Referring to FIGS. 2A and 2B, a plurality of emitters 108 are assembled or otherwise arranged on a substantially planar first substrate 104 to define the emitter array 115. In some embodiments, the first substrate 104 may be a rigid substrate, such as a Printed Circuit Board (PCB), and electrical connections may be formed between the emitters 108 of the emitter array 115 and the PCB 104 as well as between the PCB 104 and external circuitry. In some embodiments, the emitter array 115 is formed or arranged on an intermediate substrate 107, and the intermediate substrate 107 is placed or assembled on the first rigid substrate 104. The emitters 108 may be formed on the first substrate 104 (or intermediate substrate 107) using micro-transfer-printing techniques, and thus, may respectively include a broken tether or anchor portion and/or may be electrically connected by thin film conductive patterns in a serial or parallel fashion. At least some of the emitters 108 of the array 115 extend away from the first substrate 104 (or intermediate substrate 107) to a same or common height (e.g., in the Z-direction). The top surfaces of the emitters 108 may be passivated to reduce or prevent mechanical damage, for example during assembly or subsequent processing.

As shown in FIG. 2A, an optical element 112 is configured to shape or otherwise alter the respective light emissions from the emitters 108 and output a light pattern having a desired intensity and/or spatial distribution. In the examples described herein, the optical element is described as having a structured surface 101 formed on or placed on a second substrate 102 (for example, a substantially flat or planar substrate). However, the optical element 112 is not limited to structured surfaces 101 and may include other optical elements configured to provide the desired beam shaping as described herein. The second substrate 102 may be substantially transparent to the wavelength(s) or wavelength band or range of the light output from the emitters 108. The second substrate 102 is arranged or attached over the emitter array 115 with a height (e.g., in the Z-direction) that is designed or configured to match a desired or required hold-off or spacing distance between the structured surface 101 and the emitters 108 to provide the desired light pattern or beam shaping performance. For example, one or more pedestal structures 105 may be formed on and/or may extend from one or more peripheral regions (e.g., respective edges and/or respective corners) of the second substrate 102. In some embodiments, the height of the pedestals 105 is the same as or shorter than the sum of the height of the intermediate substrate 107 plus the common height of the emitters 108 above the intermediate substrate 107 plus the height or thickness of the second substrate 102.

Still referring to FIG. 2A, one or more alignment patterns (illustrated with reference to fiducial marks or structures 106 by way of example) are formed on the first substrate 104. For example, fiducial structures 106 may be placed or otherwise arranged on the first substrate 104 at respective positions that are based on or relative to the emitters 108 (e.g., adjacent a periphery of or otherwise outside of the area of the emitter array 115). In some embodiments, the fiducial marks or structures 106 may be positioned based on the positioning of the emitters 108 (e.g., adjacent a periphery of the intermediate substrate 107 including the emitters 108 thereon). That is, the periphery or boundaries of the emitter array 115 may be used to determine the position(s) of the alignment pattern(s) 106, such that the alignment pattern(s) 106 are formed based on the position of the emitters 108 on the first substrate 104. In some embodiments, the alignment patterns 106 may be alignment structures that may be recessed in or may protrude from a surface of the first substrate 104 outside of the area of the emitter array 115. For example, the alignment structures 106 may be etched into the first substrate 104, may be deposited on the first substrate 104 and patterned in the desired positions, or may be positioned on the substrate 104 using a transfer printing process.

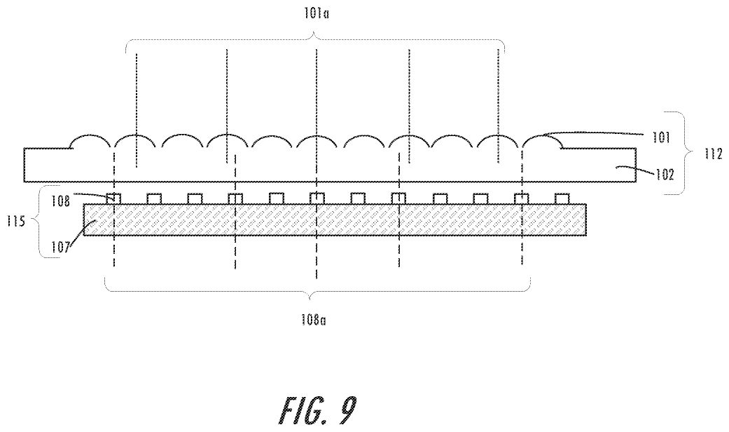

The fiducial marks or structures 106 may be used in a self-aligned process, to assemble the optical element 112 with a desired orientation (e.g., along angular dimensions (0, (p) and/or linear dimensions (X, Y, Z)) on and relative to the emitter array 115. For example, as shown in FIG. 2B, the second substrate 102 including the pedestals 105 is placed between or otherwise aligned by the fiducial marks 106, with a first or lower surface facing the first substrate 104, a second or upper surface 101 opposing the first substrate 104 and edges/corners within the fiducial marks 106. That is, the periphery or boundaries of the emitter array 115 may define the respective position(s) of the alignment patterns 106 (e.g., adjacent to respective edges and/or respective corners of the emitter array 115 or supporting intermediate substrate 107), and the alignment patterns 106 may be used to align edges and/or corners of the second substrate 102 having the structured surface 101, such that the optical element 112 may be self-aligned with the emitter array 115. As described below with reference to FIG. 9, the optical element 112 may be aligned with the emitter array 115 without requiring individual alignment of the respective emitters 108 with local optical axes 101a of the structured surface 101.

In some embodiments, pressure may be applied to the second substrate 102 such that the first/lower surface directly contacts a top surface of one or more of the emitters 108. In FIGS. 2A and 2B, an adhesive layer or pattern 103 is provided between the bottom of the pedestals 105 and the first substrate 104, and the adhesive 103 is cured while the second substrate 102 having the structured surface 101 is pushed or pressed against the top of the emitters 108, to attach or affix the optical element 112 in a desired position relative to the emitter array 115. It will be understood that the adhesive 103 may be any of various adhesives, including but not limited to one- or multiple-component epoxies, UV cured epoxy, pressure-activated adhesives, solder, or adhesive tape.

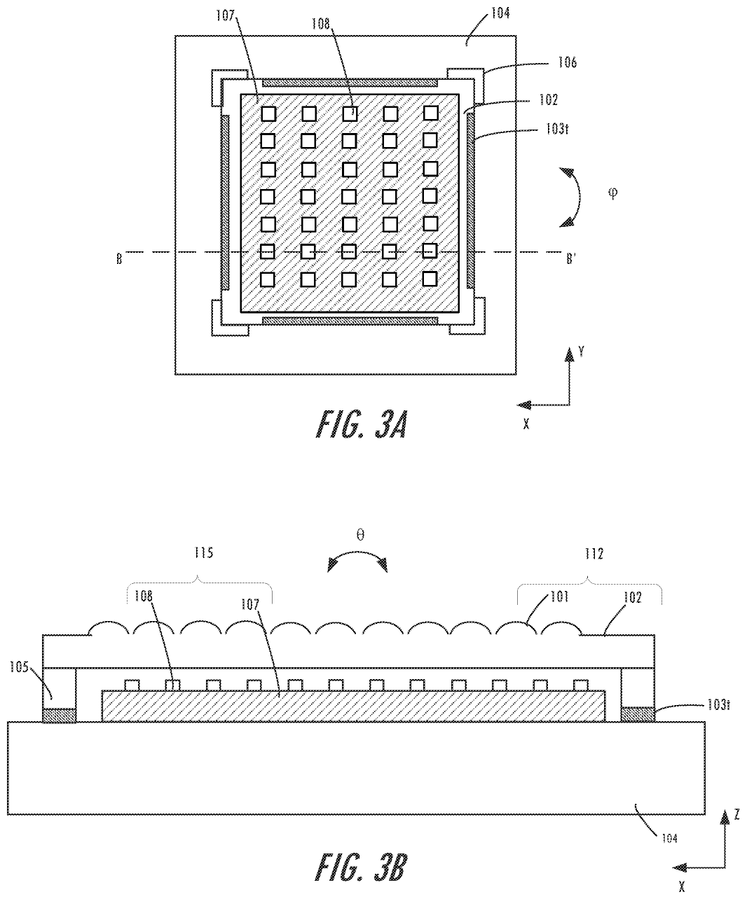

FIG. 3A is a plan view of an emitter array on a substrate that is configured for implementing self-aligned optical element(s) in accordance with some embodiments of the present disclosure. FIG. 3B is a cross-sectional view taken along line B-B′ of FIG. 3A, with the self-aligned optical element(s) mounted on the emitter array. The embodiment of FIGS. 3A and 3B may be similar to the embodiment of FIGS. 2A and 2B, with description of similar elements omitted for brevity.

Referring to FIGS. 3A and 3B, a plurality of emitters 108 are assembled or otherwise arranged on a substantially planar first substrate 104 (or in some embodiments, an intervening intermediate substrate 107) to define the emitter array 115, and a structured surface 101 is formed on or placed on a second substrate 102 to define an optical element 112 that is configured to shape or otherwise alter the respective light beams from the emitters 108 and output a light pattern having a desired spatial distribution, similar to the embodiment of FIGS. 2A and 2B. As in FIGS. 2A and 2B, the periphery or boundaries of the emitter array 115 (or supporting intermediate substrate 107) may define the position(s) of one or more alignment patterns (such as fiducial marks or structures 106), which may be used to align the optical element 112 with the emitter array 115 in a self-aligned manner.

In FIGS. 3A and 3B, the adhesive layer or pattern may be implemented by an adhesive tape 103t with a substantially uniform thickness is placed on the first substrate 104 (or on the pedestals 105) to attach or affix the optical element 112 in a desired position relative to the emitter array 115. The sum of the thickness of the adhesive tape 103t and the height of the pedestal 105 (e.g., in the Z-direction) is equal to the required or desired stand-off or spacing between the structured surface 101 and the emitters 108 to provide the desired light pattern or beam shaping performance.

As shown in FIG. 3B, the bottom surface of the second substrate 102 may be separated from (e.g., by an air gap) or may otherwise not directly contact the top surfaces of the emitters 108. The thickness of the second substrate 102 may be configured such that, together with the air gap between the second substrate 102 and the emitters 108, a sufficient stand-off or spacing distance is achieved for the patterned surface 101 to receive the respective light beams output from the emitters 108 and collectively define a light pattern having a desired spatial distribution or otherwise provide the desired optical performance.

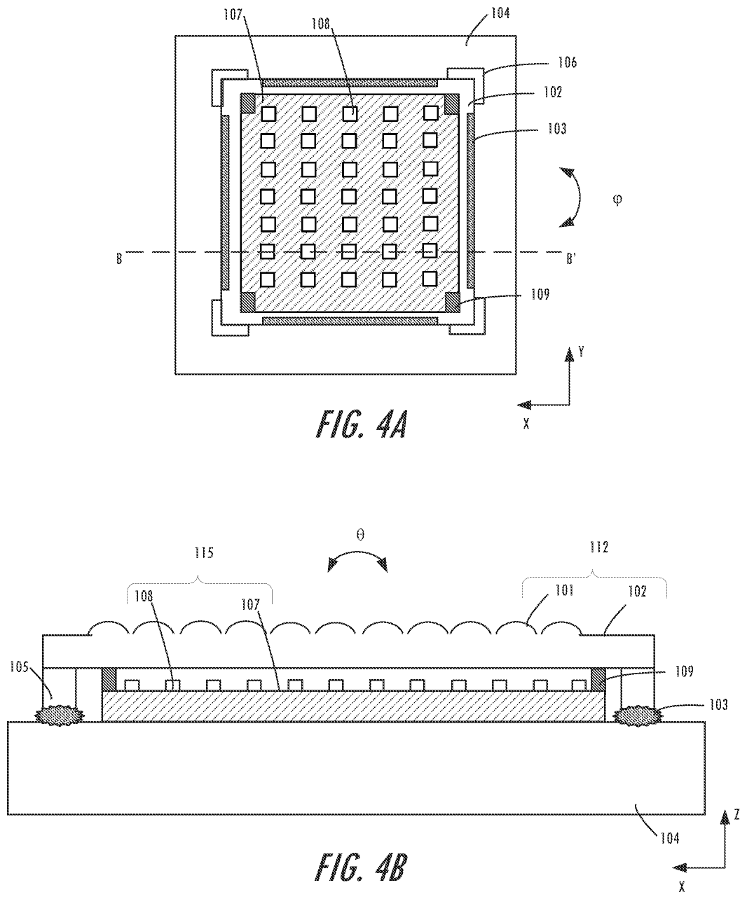

FIG. 4A is a plan view of an emitter array on a substrate that is configured for implementing self-aligned optical element(s) in accordance with some embodiments of the present disclosure. FIG. 4B is a cross-sectional view taken along line B-B′ of FIG. 4A, with the self-aligned optical element(s) mounted on the emitter array. The embodiment of FIGS. 4A and 4B may be similar to the embodiment of FIGS. 3A and 3B, with description of similar elements omitted for brevity.

Referring to FIGS. 4A and 4B, the periphery or boundaries of the emitter array 115 (or supporting intermediate substrate 107) define the position(s) of one or more alignment patterns 106 (such as fiducial marks or structures) that are used to align the optical element 112 with the emitter array 115 in a self-aligned manner. In FIGS. 4A and 4B, one or more spacer structures 109 (also referred to herein as spacers) are formed on the intermediate substrate 107 with respective heights (above the substrate 107) greater than that of the emitters 108. The second substrate 102 is positioned over the emitter array 115, aligned within or otherwise based on the alignment pattern(s) 106, and affixed to the first substrate 104 using an adhesive 103 in a similar manner as described in FIGS. 2A and 2B. The second substrate 102 has a thickness such that the air gap plus the thickness of the second substrate 102 positions the structured surface 101 with a sufficient spacing distance from the emitters 108 to receive the respective light beams output therefrom and output a light pattern having a desired spatial distribution or otherwise provide the desired optical performance.

Although illustrated in FIG. 4A as distinct spacer structures 109 positioned at corners of the intermediate substrate 107, in some embodiment the spacer 109 may be implemented as a frame structure that extends (e.g., continuously) along edges of the intermediate substrate 107 or otherwise around a periphery of the emitter array 115. Additionally or alternatively, distinct spacer structures 109 may be distributed among the emitters 108 (e.g., in a central position or other positions within the array 115). In some embodiment the spacers 109 are placed or arranged on the intermediate substrate 107, e.g., using micro-transfer printing techniques.

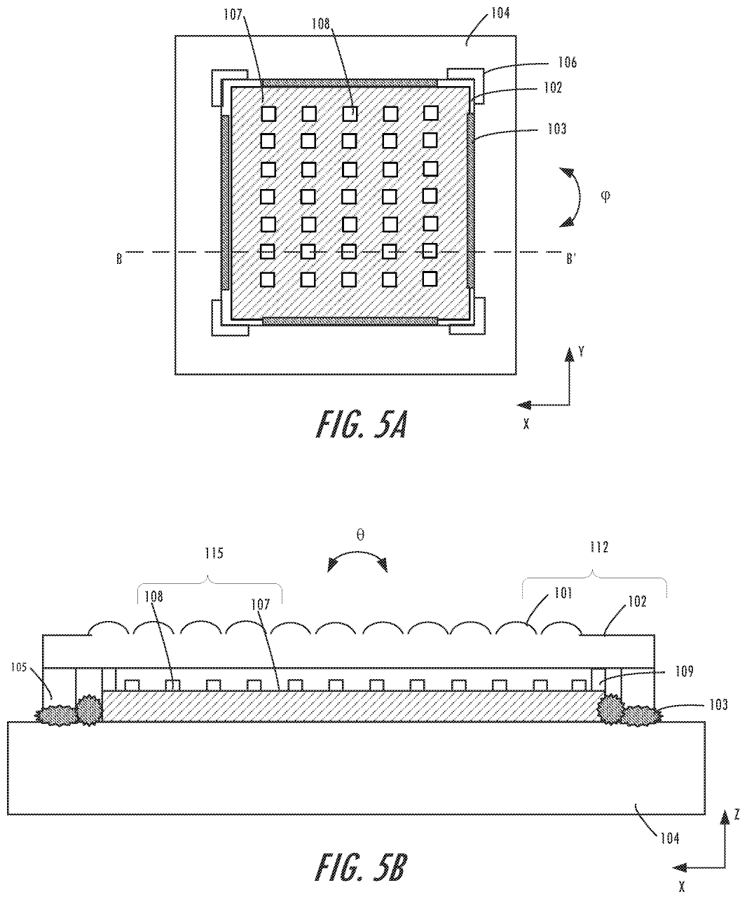

FIG. 5A is a plan view of an emitter array on a substrate that is configured for implementing self-aligned optical element(s) in accordance with some embodiments of the present disclosure. FIG. 5B is a cross-sectional view taken along line B-B′ of FIG. 5A, with the self-aligned optical element(s) mounted on the emitter array. The embodiment of FIGS. 5A and 5B may be similar to the embodiment of FIGS. 4A and 4B, with description of similar elements omitted for brevity.

Referring to FIGS. 5A and 5B, the periphery or boundaries of the emitter array 115 (or supporting intermediate substrate 107) define the position(s) of one or more alignment patterns 106 (such as fiducial marks or structures) that are used to align the optical element 112 with the emitter array 115 in a self-aligned manner. In FIGS. 5A and 5B, the alignment pattern(s) 106 are positioned closer to or directly on corners of the intermediate substrate 107, and the adhesive 103 may extend immediately adjacent or directly along edges of the intermediate substrate 107.

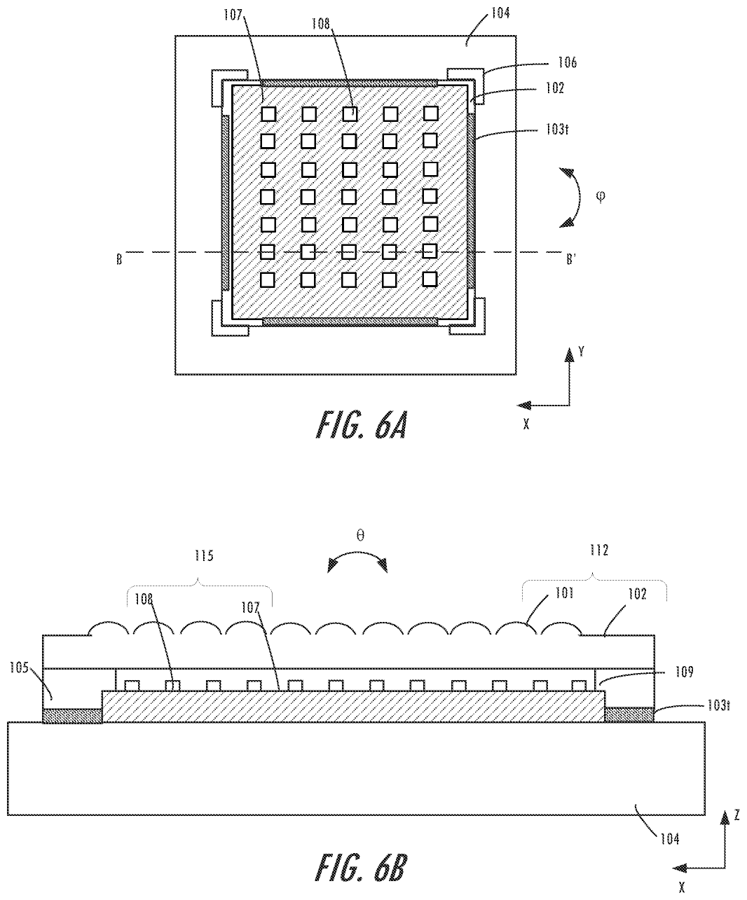

In the example of FIGS. 5A and 5B, the spacers 109′ may be etched from or otherwise integral to the intermediate substrate 107, e.g., etched from a die. In some embodiments the spacers 109′ may be integral to the second substrate 102. For example, the spacers 109′ may be formed by etching away areas or portions of the second substrate 102 that are to be positioned above the emitter array 108, thereby forming a frame that is integral to the second substrate 102. In some embodiments the pedestals 105 are attached to the intermediate substrate 107 alone, or to both the intermediate substrate 107 and the first substrate 104 (as shown in FIGS. 6A and 6B).

FIG. 6A is a plan view of an emitter array on a substrate that is configured for implementing self-aligned optical element(s) in accordance with some embodiments of the present disclosure. FIG. 6B is a cross-sectional view taken along line B-B′ of FIG. 6A, with the self-aligned optical element(s) mounted on the emitter array. The embodiment of FIGS. 6A and 6B may be similar to the embodiment of FIGS. 5A and 5B, with description of similar elements omitted for brevity.

Referring to FIGS. 6A and 6B, the periphery or boundaries of the emitter array 115 (or supporting intermediate substrate 107) define the position(s) of one or more alignment patterns 106 (such as fiducial marks or structures) that are used to align the optical element 112 with the emitter array 115 in a self-aligned manner. In FIGS. 6A and 6B, the pedestal structure(s) 105 define the spacing between the emitters 108 and the second substrate 102, without the use of spacers 109/109′. In particular, the pedestal structure(s) 105 provide both attachment of the second substrate 102 to the first substrate 104 (e.g., using adhesive tape 103t therebetween), and also extend onto the surface of the intermediate substrate 107 (which includes the emitters 108 thereon) to provide the desired spacing between the emitters 108 and the structured surface 101. In some embodiments, the pedestal structure 105 may be implemented as a frame structure that extends (e.g., continuously) along the surface and edges of the intermediate substrate 107, or otherwise around a periphery of the emitter array 115.

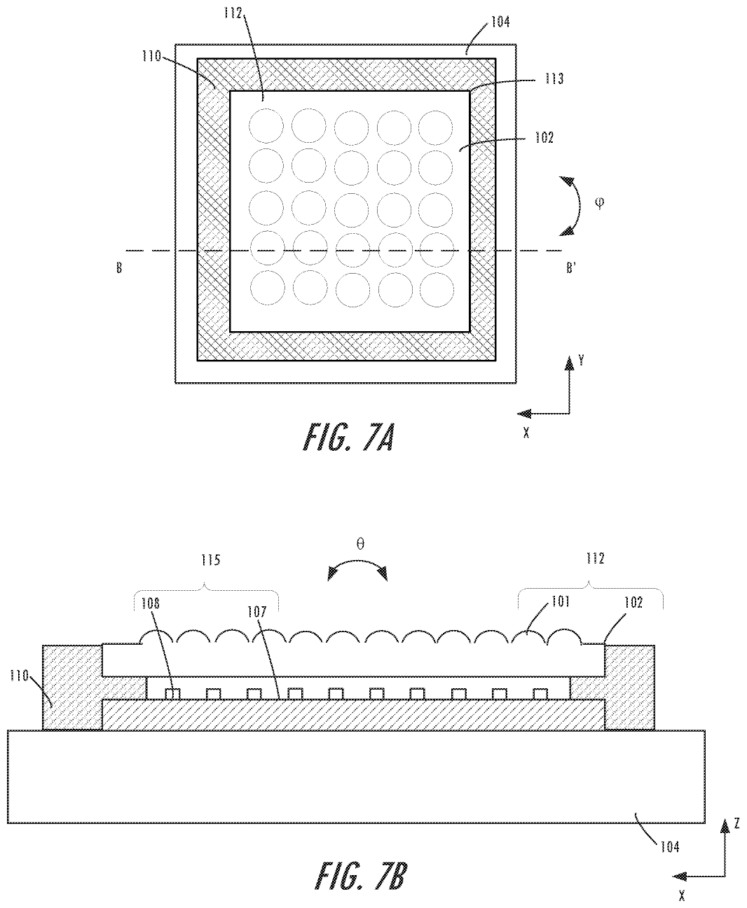

FIG. 7A is a plan view of an emitter array on a substrate that is configured for implementing self-aligned optical element(s) in accordance with some embodiments of the present disclosure. FIG. 7B is a cross-sectional view taken along line B-B′ of FIG. 7A, with the self-aligned optical element(s) mounted on the emitter array. The embodiment of FIGS. 7A and 7B may be similar to the embodiment of FIGS. 6A and 6B, with description of similar elements omitted for brevity.

Referring to FIGS. 7A and 7B, the periphery or boundaries of the emitter array 115 (or supporting intermediate substrate 107) define the position(s) of one or more alignment patterns that are used to align the optical element 112 with the emitter array 115 in a self-aligned manner. In FIGS. 7A and 7B, the alignment pattern may be provided by a corner 113 of a frame 110 that is positioned adjacent a periphery of the emitters 108. The frame 110 is dimensioned be greater than an area of the emitter array 115. For example, length and width dimensions of the frame 110 may be configured based on and exceeding the length and width dimensions of the intermediate substrate 107, or otherwise larger than the dimensions occupied by the emitter array 115.

In particular, as shown in FIG. 7A, a frame 110 (e.g., a multi-layer ceramic or glass frame) is positioned over the substrate 104 and/or 107 having the emitter array 115 thereon, and is pushed or pressed toward a specific corner forming a reference corner 113 at the intersection of two reference planes. This provides micron level placement accuracy relative to the emitter array 115, without the need for an active alignment. A planar beam shaping optical element 112 (e.g. including a structured surface 101 on a second substrate 102) is then placed on top of the frame 110 and pushed or pressed into the same reference corner 113 for micron level placement accuracy, after which the assembly may be fixed in place with an adhesive (not shown). The coefficient of thermal expansion (CTE) of the second substrate 102 of the beam shaping optical element 112 may be larger than the CTE of the intermediate substrate 107 containing the emitter array 115 so that the emitter array 115 and the optical element 112 may expand together (as the emitter array 115 may typically be subjected to higher operating temperatures than the beam shaping optical element 112.

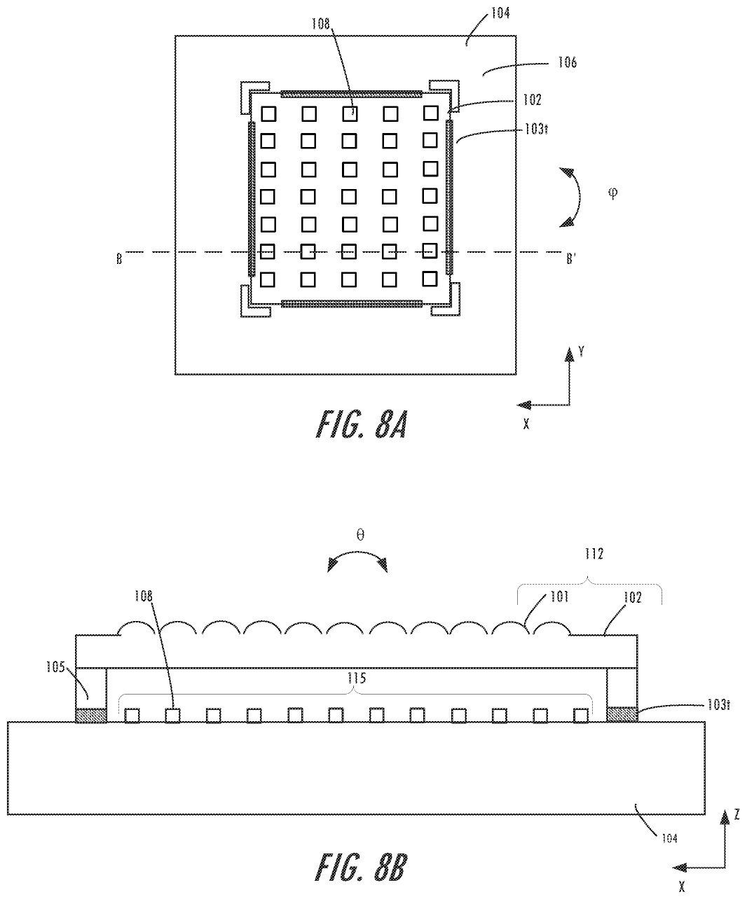

FIGS. 8A and 8B are plan and cross-sectional views, respectively, of an emitter array on a substrate that is configured for implementing self-aligned optical element(s) in accordance with some embodiments of the present disclosure. FIGS. 8A and 8B illustrate an embodiment in which the emitters 108 are provided (e.g., by transfer printing or other methods) directly on the first substrate 104 to define the emitter array 115 (i.e., without the intermediate substrate 107). The alignment pattern(s) 106 are thus oriented relative to the emitters 108 themselves (e.g. adjacent a periphery of the array 115), rather than along edges or and/or corners of the intermediate substrate 107. The emitters 108 may be electrically connected by conductive interconnections in the substrate 104 and/or on the substrate 104 (e.g., thin film interconnections). While omission of the intermediate substrate 107 is illustrated in the examples of FIGS. 8A and 8B with reference to a configuration similar to the embodiment of FIGS. 3A and 3B, it will be understood that the intermediate substrate 107 may be omitted and the emitters 108 may be provided directly on the first substrate 104 in combination with the optical elements 112 and attachment methods of any of the embodiments described herein.

Likewise, in any of the embodiments described herein, the air gap between the emitter array 115 and the beam shaping optic 112 may be filled with transparent optical quality silicone (or other material with a relatively high refractive index n) to protect the assembly from condensed moisture and to improve the optical transmission through the assembly. For example, a higher index material (e.g., 1.5) in comparison to air (1.0) may be used to fill the gap(s) between the emitters 108 and/or between the emitters 108 and the second substrate 102 in some embodiments.

FIG. 9 is an enlarged cross-sectional view illustrating local optical axes of the optical element relative to respective optical axes of the emitters according to some embodiments of the present disclosure. As shown in FIG. 9, the respective local optical axes 101a defined by the structured surface 101 of the optical element 112 may be misaligned with or independent of respective optical axes 108a of the emitters 108. In particular, in the example of FIG. 9, the respective optical axes 108a of centrally-located emitter(s) 108a may be more closely aligned with the respective local optical axes 101a of the structured surface 101 than those of peripherally-located emitter(s) 108. More generally, the structured surface 101 of the optical element 112 may be designed or otherwise configured to provide the desired beam shaping independent of alignment of the respective local optical axes 101a thereof with the respective optical axes 108a of the light sources 108.

Lidar systems and arrays described herein may be applied to ADAS (Advanced Driver Assistance Systems), autonomous vehicles, UAVs (unmanned aerial vehicles), industrial automation, robotics, biometrics, modeling, augmented and virtual reality, 3D mapping, and security. In some embodiments, the emitter array may include a non-native substrate that is different from a source wafer or substrate on which the emitters were formed (e.g., a curved or flexible substrate) having thousands of discrete emitter elements electrically connected in series (e.g., anode-to-cathode) and/or parallel thereon, with the driver circuit implemented by driver transistors integrated on the non-native substrate adjacent respective rows and/or columns of the emitter array, as described for example in U.S. Patent Application Publication No. 2018/0301872 to Burroughs et al., the disclosure of which is incorporated by reference herein. Beam shaping may also be achieved using optical elements and associated structures as described as described for example in U.S. Patent Application Publication No. 2018/0301874 to Burroughs et al., the disclosure of which is incorporated by reference herein.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

The example embodiments are mainly described in terms of particular methods and devices provided in particular implementations. However, the methods and devices may operate effectively in other implementations. Phrases such as “example embodiment”, “one embodiment” and “another embodiment” may refer to the same or different embodiments as well as to multiple embodiments. The embodiments will be described with respect to systems and/or devices having certain components. However, the systems and/or devices may include fewer or additional components than those shown, and variations in the arrangement and type of the components may be made without departing from the scope of the inventive concepts.

The example embodiments will also be described in the context of particular methods having certain steps or operations. However, the methods and devices may operate effectively for other methods having different and/or additional steps/operations and steps/operations in different orders that are not inconsistent with the example embodiments. Thus, the present inventive concepts are not intended to be limited to the embodiments shown, but are to be accorded the widest scope consistent with the principles and features described herein.

It will be understood that when an element is referred to or illustrated as being “on,” “connected,” or “coupled” to another element, it can be directly on, connected, or coupled to the other element, or intervening elements may be present. In contrast, when an element is referred to as being “directly on,” “directly connected,” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

It will also be understood that the term “and/or” as used herein refers to and encompasses any and all possible combinations of one or more of the associated listed items. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

Although the invention has been described herein with reference to various embodiments, it will be appreciated that further variations and modifications may be made within the scope and spirit of the principles of the invention. While specific terms are employed, they are used in a generic and descriptive sense only and not for purposes of limitation, the scope of the present invention being set forth in the following claims.

1. An optical emitter device, comprising:
a plurality of emitters on a first substrate;
one or more alignment patterns on the first substrate, wherein the one or more alignment patterns are positioned relative to the plurality of emitters; and
at least one optical element arranged to receive respective light emissions from the plurality of emitters, wherein the at least one optical element is oriented based on the one or more alignment patterns.

2. The optical emitter device of claim 1, wherein the emitters are arranged in an array, and wherein the one or more alignment patterns are positioned adjacent a periphery of the array.

3. The optical emitter device of claim 2, wherein the one or more alignment patterns comprise fiducial structures that extend along the periphery of the array.

4. The optical emitter device of claim 3, further comprising an intermediate substrate having the plurality of emitters thereon, wherein the intermediate substrate is on a surface of the first substrate, and wherein the fiducial structures extend along edges of the intermediate substrate.

5. The optical emitter device of claim 3, wherein the fiducial structures protrude from a surface of the first substrate.

6. The optical emitter device of claim 1, wherein the at least one optical element comprises a second substrate having edges and/or corners that are aligned based on the one or more alignment patterns.

7. The optical emitter device of claim 6, wherein the second substrate comprises a first surface facing the plurality of emitters and a second surface opposite the first surface, wherein the second surface comprises a structured optical surface.

8. The optical emitter device of claim 7, wherein the first surface of the second substrate directly contacts one or more of the emitters.

9. The optical emitter device of claim 7, wherein the first surface of the second substrate is separated from the emitters by a gap therebetween.

10. The optical emitter device of claim 7, further comprising one or more pedestal structures that attach the second substrate to the first substrate, wherein a height of the one or more pedestal structures is configured to provide a portion of a spacing between the emitters and the second surface of the second substrate.

11. The optical emitter device of claim 10, further comprising:
an adhesive pattern between the one or more pedestal structures and the first substrate, wherein a thickness of the adhesive pattern is configured to provide a portion of the spacing.

12. The optical emitter device of claim 10, further comprising:
one or more spacer structures between the first substrate and the first surface of the second substrate, wherein a height of the one or more spacer structures is configured to provide a portion of the spacing.

13. The optical emitter device of claim 12, wherein the one or more spacer structures is integral to the second substrate or the intermediate substrate.

14. The optical emitter device of claim 10, wherein the one or more pedestal structures extend onto the intermediate substrate to provide a portion of the spacing.

15. The optical emitter device of claim 7, wherein the one or more alignment patterns comprise a corner of a frame structure that is positioned adjacent the periphery of the array.

16. The optical emitter device of claim 7, wherein a coefficient of thermal expansion (CTE) of the second substrate is greater than that of the first substrate and/or the intermediate substrate.

17. The optical emitter device of claim 7, wherein respective local optical axes of the structured optical surface are oriented independent of respective optical axes of the plurality of emitters.

18. The optical emitter device of claim 7, wherein the structured optical surface comprises a diffractive optical element.

19. The optical emitter device of claim 4, wherein the first substrate and/or the intermediate substrate having the emitters thereon is a non-native substrate.

20. A method of fabricating an optical emitter device, the method comprising:
providing a plurality of emitters on a first substrate;
providing one or more alignment patterns on the first substrate, wherein the one or more alignment patterns are positioned relative to the plurality of emitters; and
arranging at least one optical element to receive respective light emissions from the plurality of emitters, wherein the at least one optical element is oriented based on the one or more alignment patterns.

21. The method of claim 20, wherein providing the emitters and providing the one or more alignment patterns comprises:
providing the emitters in an array on the first substrate; and
providing the one or more alignment patterns adjacent a periphery of the array.

22. The method of claim 21, wherein providing the one or more alignment patterns comprises:
providing fiducial structures on the first substrate that extend along the periphery of the array.

23. The method of claim 22, wherein providing the emitters on the first substrate comprises:
providing the emitters on an intermediate substrate; and
providing the intermediate substrate on a surface of the first substrate,
wherein the fiducial structures extend along edges of the intermediate substrate.

24. The method of claim 22, wherein the fiducial structures protrude from a surface of the first substrate, optionally wherein providing the fiducial structures comprises transfer-printing the fiducial structures on the first substrate.

25. The method of claim 20, wherein the at least one optical element comprises a second substrate, and wherein arranging the at least one optical element comprises:
aligning edges and/or corners of the second substrate based on the one or more alignment patterns.

26. The method of claim 25, wherein the second substrate comprises a first surface facing the plurality of emitters and a second surface opposite the first surface, wherein the second surface comprises a structured optical surface.

27. The method of claim 26, further comprising:
attaching the second substrate to the first substrate by one or more pedestal structures, wherein a height of the one or more pedestal structures is configured to provide a portion of a spacing between the emitters and the second surface of the second substrate.

28. The method of claim 27, further comprising:
providing an adhesive pattern on the one or more pedestal structures and/or on the first substrate, wherein a thickness of the adhesive pattern is configured to provide a portion of the spacing.

29. The method of claim 27, further comprising:
providing one or more spacer structures on the first substrate, wherein a height of the one or more spacer structures is configured to provide a portion of the spacing,
optionally wherein providing the one or more spacer structures is performed using a transfer-printing process.

30. The method of claim 26, wherein providing the one or more alignment patterns comprises:
providing a frame structure on the first substrate adjacent the periphery of the array, wherein the one or more alignment patterns comprise a corner of the frame structure.

31. The method of claim 20, wherein providing the emitters comprises:
transferring the emitters from a native source substrate to the first substrate or to the intermediate substrate using a transfer-printing process.

32. The optical emitter device of claim 1, wherein the optical emitter device is configured to be coupled to a vehicle and oriented relative to an intended direction of travel of the vehicle.
